(19) United States
(12) Patent Application Publication
(10) Pub. No.: US 2022/0365716 A1
(43) Pub. Date: Nov. 17, 2022

(54) COMPUTING STORAGE ARCHITECTURE WITH MULTI-STORAGE PROCESSING CORES

(71) Applicant: Western Digital Technologies, Inc., San Jose, CA (US)

(72) Inventors: In-Soo Yoon, Los Gatos, CA (US); Venky Ramachandra, San Jose, CA (US)

(21) Appl. No.: 17/318,956

(22) Filed: May 12, 2021

(51) Int. Cl. G06F 3/06; G11C 7/10; G06N 20/00

(52) U.S. Cl. CPC G06F 3/0659; G06F 3/0658; G06F 3/0613; G06F 3/0679; G11C 7/1012; G06N 20/00

(57) ABSTRACT

A computing storage architecture is disclosed. Memory devices may incorporate distributed processors and memory. The devices can be arranged using multiple packages, each package including one, or multiple, dies. In one aspect of the disclosure, any of the processors on a first die may transfer data to and from any processor on a second die internally within the device without having to pass through an external storage controller. In another aspect of the disclosure, a multi-package processing architecture allows for both in-package and inter-channel data transfers between processors within the same device. In still another aspect of the disclosure, one or more processors may include a preemptive scheduler circuit, which enables a processor to interrupt an ongoing lower priority transmission and to immediately transfer data.

### BACKGROUND

### Field

This disclosure is generally related to memory and processor operations, and more specifically to a computing architecture enabling direct inter-die and inter-package communications.

### Background

With modern commercial processing and solid state memory techniques achieving unprecedented speeds in mainstream electronics applications in recent years, attention of manufacturers has increasingly turned toward memory architectures that provide increased die area for multiprocessing applications. The desired result is a multiprocessor system that overcomes drawbacks commonly seen with current processor architectures, to implement computationally-intensive applications with a new level of sophistication.

Despite this trend and these advances, processor-to-memory bottlenecks persist in conventional architectures. For example, processor communications between different memory dies are ordinarily mediated by an external controller. As a result, these multi-processing devices encounter bottlenecks due to latencies at the controller. Moreover, because communications are governed by the controller, the memory/processor architectures have no ability to initiate data transfers. These inherent latencies of memory architectures place practical limits on the extent to which advanced processing applications can be realized.

### SUMMARY

One aspect of a memory device is disclosed herein. The memory device includes a plurality of packages. Each package comprises a plurality of dies having processors and memory cells. The dies are coupled together within the package and with the other packages via conductors. Any of the processors on a first die in one of the packages is configured to transfer data internally within the device to any of the processors on a second die in any of the packages.

Another aspect of a device includes an architecture for intra-package and inter-channel processor communication. The device includes a plurality of packages on a substrate. Each package includes a plurality of dies. Each die has processors and memory cells. The dies are coupled together within the package and with others of the packages via conductors. Any of the processors on a first die in one of the packages is configured to transfer data internally within the device between the processor and another processor or memory cells on a second die in any of the packages.

Another aspect of an apparatus is also disclosed. The apparatus includes a package arranged on a substrate. The package includes a plurality of dies. Each die has processors and an input/output (I/O) interface coupled to the other dies via conductors and configured to connect to an external storage controller. The I/O interface is configured to enable a processor on one of the dies to perform an in-package data transfer to or from another processor on another of the dies and to perform inter-channel data transfers with processors outside the apparatus.

It is understood that other aspects of the multiprocessor computing architecture will become readily apparent to those skilled in the art from the following detailed description, wherein various aspects of apparatuses and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of the present invention will now be presented in the detailed description by way of example, and not by way of limitation, with reference to the accompanying drawings, wherein:

FIG. 1 is a block diagram of a multiprocessor circuit including memory packages connected together by a storage controller.

FIG. 2 is a block diagram of a distributed multiprocessor and memory device that performs intra-package communication using an internal bus.

FIG. 3 is a block diagram of a distributed multiprocessor and memory device that performs intra-package communication using an internal interface circuit.

FIG. 4 is a block diagram of a distributed multiprocessor and memory device that performs intra-package and inter-channel communication using an internal interface circuit.

FIG. 5 is a block diagram of a distributed memory and processor architecture.

FIG. 6 is a block diagram of a distributed multiprocessor and memory device that performs intra-package and inter-channel communication using an internal I/O interface.

FIG. 7 is a block diagram of an exemplary portion of the circuit of FIG. 6.

FIG. 8 is a flowchart describing intra-package and inter-channel communication.

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific details for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention. Acronyms and other descriptive terminology may be used merely for convenience and clarity and are not intended to limit the scope of the invention.

The words “exemplary” and “example” are used herein to mean serving as an example, instance, or illustration. Any exemplary embodiment described herein as “exemplary” is not necessarily to be construed as preferred or advantageous over other exemplary embodiments. Likewise, the term “exemplary embodiment” of an apparatus, method or article of manufacture does not require that all exemplary embodiments of the invention include the described components, structure, features, functionality, processes, advantages, benefits, or modes of operation.

The principles of this disclosure may apply to a number of state-of-the-art memory architectures, including without limitation CMOS Bonded Array (CBA)). Wafer-to-wafer bonding may allow for three-dimensional memory/processor devices as described herein. For example, the memory cells may be placed on one wafer, the CMOS array including control logic on another wafer, and the wafers may then be bonded together, e.g., using copper or another suitable element. The sandwiched die may be placed in a single package. In some cases, the die with the control logic may have die area remaining for other applications. Accordingly, in one aspect of the disclosure, the available regions on the CMOS die adjacent the control logic are populated with a plurality of processors. In this example of CBA, one die can include the memory core, while the other bonded die can include the LDPC engine, security engine, I/O interface, and multiprocessors. For purposes of this disclosure, a “die” may also be deemed to include CBA sandwiched-dies and similar 3D die array technologies, as well as conventional semiconductor die technologies.

The principles of this disclosure may be implemented by different types of memory devices. These devices may incorporate multiple processors (referred to herein sometimes as “multiprocessor” or “multiprocessors”) and other elements. Their components may be implemented using electronic hardware, computer software, or any combination thereof.

By way of example, an element, component, or any combination thereof of a memory device may be implemented using one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. The one or more processors may execute software and firmware. Software and firmware shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, object code source code, or otherwise.

Accordingly, in one or more example embodiments, the functions described may be implemented in hardware, software, or any combination thereof. If implemented in software, the functions may be stored on or encoded as one or more instructions or code on a computer-readable medium. The memory devices herein may further include distributed processors positioned at different locations throughout the circuit, including adjacent one or more memory arrays. The memory devices and corresponding multiprocessors may be formed on one or more dies. In some configurations, the dies are included in a package, such as a ceramic, plastic or other type of casing with conductors for housing one or more dies. In some embodiments, the dies may be arranged at various positions on one or more substrates. The dies may be stacked. For example, one die may incorporate the memory circuits, and another die stacked vertically and opposing the first die may incorporate control circuits. Either die may include one or more processors. In some configurations, the memory device may include multiple packages, each package having multiple dies. The packages may likewise be arranged on a surface or substrate (such as a printed circuit board, for example). The memory device may include an array of packages. Like the dies, the packages may be distributed adjacent one another on a substrate, or they may be stacked. In other arrangements, the processors may be distributed between the memories on a die, or positioned otherwise.

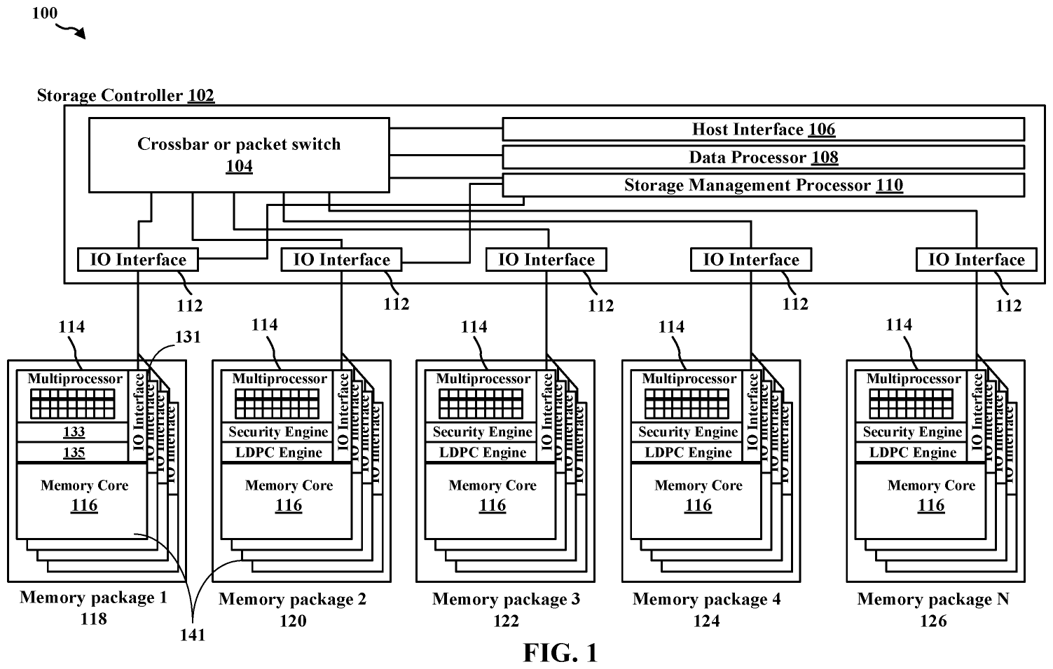

FIG. 1 is a block diagram of a multiprocessor circuit 100 including memory packages 118, 120, 122, 124, 126 connected to a storage controller 102. The storage controller 102 may, for example, be a solid state drive (SSD) controller used in an SSD drive. Each of the memory packages includes one or more dies 141 having a multiprocessor 114, a memory core 116, a security engine 133, a low-density parity check (LDPC) engine 135, and an I/O interface 131. As shown in the example, four dies 141 including similar circuitry are included and coupled together within each memory package (e.g., 118). Storage controller 102 includes host interface 106, data processor 108, and storage management processor (SMP) 110, each of which are respectively coupled to crossbar or packet switch module 104. The storage controller 102 can initiate and effect read, write and other data transfer operations between the different processing and memory elements on the different die. The SMP 110 may arbitrate use of resources by the storage controller 102.

The I/O interface 131 of each die 141 on each memory package 118, 120, 122, etc., is coupled to a respective I/O interface 112 on the storage controller 102. Each I/O interface 112 on the storage controller 102 is electrically coupled to the crossbar or packet switch module 104. In addition, the SMP 110 is coupled to each I/O interface, although to avoid unduly obscuring the figure with excessive wiring, SMP 110 is only shown as coupled to the first two I/O interface elements 112 on the left. One task of the crossbar or packet switch module 104 is to route data to the appropriate location; for example, crossbar 104 may receive a packet from one of the source processors on a die 141 and forward the packet under control of SMP 110 to its destination processor.

The memory packages of FIG. 1 are each coupled to a conventional storage controller for processor-to-processor data transfer or other operations, which currently impedes the speed and efficiency of these inter-channel or intra-package (e.g., between dies in a package) data transfers. Each of the individual packages (or dies) uses a separate I/O interface 131. Firmware for symmetric multiprocessing is needed to process the data using these multiple memory devices. The crossbar/packet switch module 102 must be used to control the transfer of each data packet, regardless of whether the data transfer is internal or instead is for external memory operations from a host. Additional latencies may result from the SMP 110 being involved in other tasks or waiting on a result. The use of the storage controller 102 for all data transfers in a multiprocessor context can add significant latencies to the overall data transfer process, and in fact, represents a significant limitation in highly sophisticated multiprocessing techniques such as artificial intelligence, self-driving cars, and the like, in which high speeds and low latencies are crucial for performance.

The fact that internal communications typically must be routed using the storage controller 102 and storage management processor 110 not only adds significant latencies to data transfers, writes and reads, but also fails to provide a mechanism for memory-side initiated data communication. As an example of conventional architectures, for a given computing task assigned from a first memory package to a second memory package, one die from the first package typically is assigned to complete the task. The storage management processor polls the device to determine whether the task is complete. If not, the SMP 110 typically then turns to another data transfer as it waits for the transfer to finish before returning to retrieve the data from package 1. The SMP 110 then may interpret the data and wait for yet another available transfer slot to finally send the data to package 2. These delays are largely or wholly resolved by embodiments of the present disclosure.

Further, for the memory packages 118, 120, etc. there exists no mechanism to prioritize data transfers. Rather, this capability rests solely with the storage controller 102. This limitation can amount to a significant impediment for artificial intelligence and machine learning applications, for example, where a processor's ability to make a high priority data transfer is crucial.

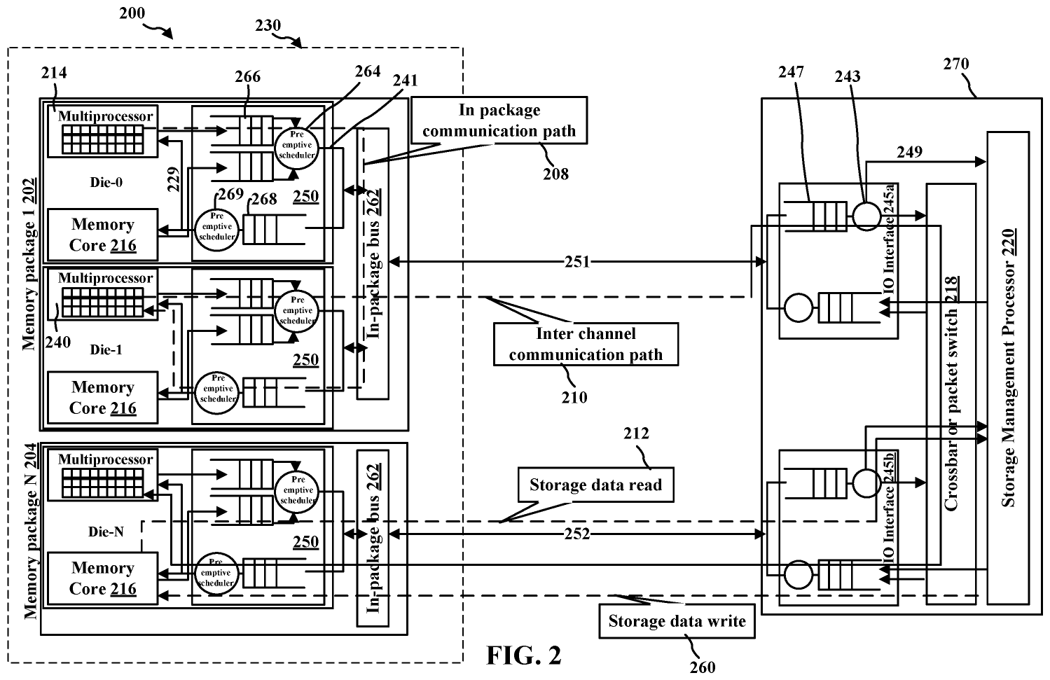

For purposes of the figures, the multiprocessors (e.g., multiprocessor 214 of FIG. 2) as described herein may be shown as a single block within a given area of a die (e.g., using CMOS). In some embodiments, the processors may be configured to occupy a particular space on the die. However, for purposes of this disclosure, the term “multiprocessor(s)” can broadly be construed to include a plurality of processors in any arrangement on a die. For example, “multiprocessor(s)” as described herein may include a distributed processor architecture, in which the processors are positioned in locations between groups of adjacent memory arrays. In addition, the term “memory core” may also be illustrated in block form (e.g., memory core 216). The term “memory core” is likewise used herein, in part, to refer to a region of a die in which a plurality of memory planes, blocks or arrays are positioned. However, for purposes of this disclosure, the term “memory core” is intended to be broadly construed to encompass virtually any type of arrangement of memory cells on a device, regardless of the location of the individual memory cells on the die.

In one aspect of the disclosure, a multiple processor and memory architecture is disclosed. A memory device can include one or more packages. Within each package, one or more die may reside in adjacent or stacked arrangements. In various embodiments, bi-directional communications can be configured to occur between processors in the device without requiring the intervention of, or introduction of latencies by, a storage controller. For example, in some embodiments, processors within the same die or residing on different dies in the same package can effect bi-directional data transfers directly, within the device. In other embodiments, processors located on dies in different packages can transfer data directly without the need for a storage controller.

In still other embodiments, the memory device as described herein may include an I/O interface configured to support both bi-directional communication as described above, and preemptive priority transfers of multi-priority packets. As one example, the data packets used in the architecture described herein can take the following form:

| | | | | |
|---|---|---|---|---|
| Header | Destination | Source | Payload | CRC (and/or) |
| | processor | processor | | ECC |

Data Packet

In various embodiments, processors that are exchanging data can either share a physical link, or they may use separate links such as for use in intensive data exchanges where higher bandwidths are desirable. In addition, in another aspect of the disclosure, the communications can use multiple priority levels, which also can use either shared or separate channels. For example, one or more dedicated data channels may be used for higher priority communications. The preemptive schedulers according to certain embodiments (as described below) can also perform hardware interrupts to immediately schedule and initiate very high priority communications. These aspects of the architecture described herein overcome the traditional memory and processing bottlenecks of multiprocessors and as noted, are especially suitable for high-performance tasks like for use in aircraft or spacecraft, artificial intelligence, robotics, machine learning, intensive calculations and other applications.

In some embodiments, the transmission between processors in different packages can be initiated either internally by a processor within the device, or through a storage controller. Further, the devices described herein can communicate with the storage controller to receive external writes or to perform read operations. The device can also incorporate a crossbar or packet switch into its own I/O interface so that the crossbar or packet switch can independently receive packets from a source processor and forward it to a destination processor.

FIG. 2 is a block diagram of a distributed multiprocessor and memory device 200 that performs intra-package communication using an internal bus. The device 200 may include from one to multiple memory packages, where memory package 1 is labeled 202 and some memory package 204 is labeled N to indicate that the device may use up to N packages, where N can include any integer greater than one. For purposes of this example, the N packages are positioned on a substrate or surface such as a circuit board, and can form a single device 230 on the surface. However, for purposes of this disclosure, the packages may include other numbers of substrates, and other orientations altogether. For example, the packages may be stacked, or the substrates each holding a plurality of packages may be stacked or formed vertically, all without departing from the spirit and scope of the disclosure.

In this embodiment, memory package 1 (202) includes two dies (die 0 and die 1). However, for purposes of this disclosure, a larger number of dies may be included within a package. In addition, different die configurations (stacked, three-dimensional, etc.) may be used in a package. Each die includes a multiprocessor 214. While the multiprocessor 214 is shown in this example as localized on the die, in practice, the processors or cores thereof of the multiprocessor 214 may be oriented in any suitable manner on the die. For example, the processors may be distributed across the die between arrays of adjacent memory cells.

The memory core 216 is similar in that, while shown schematically as one object, the memory arrays (pages, blocks, planes, etc.) may be distributed throughout the die, located on one portion of a sandwiched die (e.g., a CBA implementation), or otherwise arranged on the die without departing from the scope of the present disclosure. Thus the memory core may refer to a large number of memory cells in a given region, or in disparate regions, of a die. While die-0, die-1, and die-N are disclosed, the number N in this context need not be the same as the package and is intended primarily to illustrate that any number of dies may be present within a package, and overall on the memory device 230.

Referring still to FIG. 2, an I/O interface circuit 250 is shown on each die. The I/O interface may include one or more memory queues 266, 268, which may represent buffers or registers for transferring cached or latched data incoming to a processor or memory location on the die or outgoing to another location on another die or package. The I/O interface 250 may include other digital and analog circuits as necessary for proper functioning of the circuitry on a die.

In this aspect of the disclosure, direct die-to-die data transfers can be initiated and performed internally within the device 230 between source and destination processors on any die within a package without use of the storage controller. In addition, in one embodiment the memory device may include an individual memory package 202 capable of direct communication from a first die to a second die that no longer have to be fed through the storage controller 270. The new architecture greatly increases the speed, efficiency and bandwidth of the multiprocessor data exchanges while reducing latencies substantially.

Referring back to the I/O interface 250 of FIG. 2, an embodiment of the architecture is described with reference to memory package 1 (202) which includes, for ease of illustration, two dies 0 and 1. One of the processors in multiprocessor 214 may transfer data destined for another processor in multiprocessor 214. This transfer can be performed within multiprocessor 214. In addition, local memory accesses to memory core 216 can be performed using data bus 229. In the embodiment shown, each of the packages includes in-package bus 262, which is coupled to the I/O interfaces 250 within the package as well as to data bus 251. In some embodiments, data from a multiprocessor 214 can be transmitted via queue 266 of I/O interface and thereafter across bus 241 to be received in queue 268 for scheduling a write operation, which can be received on another die in the same package 202.

In another aspect of the disclosure, a processor in multiprocessor 214 on die-0 can transfer data to and from a processor on die-1 using in package bus 262. Thus, inter-die data transfers within memory package 1 (202) can be initiated by a processor on any die in the package, and can be effected and received using in-package bus 262 to route the data to a processor in the multiprocessors 214 of die-1 or die-0. Because the data transfer no longer has to be routed through the storage controller 270, latencies associated with the transfer can be dramatically reduced. The storage controller 270 and SMP 220 can still be used for external read and write operations, or external data transfers by one of the processors in multiprocessor 214. In addition inter-channel data transfers in this arrangement can be conducted using the storage controller 270.

In another aspect of the disclosure, the I/O interface 250 can include one or more preemptive scheduler circuits 264. As noted above, processors in conventional multiprocessor systems have no ability to initiate data transfers with different priorities. Rather, this procedure can only be performed by the storage controller 270. In the embodiments shown, the multiprocessor 214 (or any processor therein) may have a high priority data transfer that should take precedence over any existing activity. The preemptive scheduler 261 may be a hardware logic device (or a specialized processing device, DSP, FPGA, or the like) that receives the high priority command from the processor on die-0 (e.g., to transfer data to a processor on die-1). The preemptive scheduler 264 may thereupon suspend lower priority transfers, such as by temporarily storing data in the available registers in queue 266, and may transfer the high priority data immediately. In this example, the data may be sent over the bus 262 via path 241 directly to the corresponding destination processor, without further delay. The preemptive scheduler 264 may thereafter resume lower or regular priority data transfers. Additional preemptive schedulers 269 may be placed in the receive path 229 of multiprocessor 214 and memory core 216, e.g., to enable processors to initiate and/or receive high priority data transfers. In other embodiments, the preemptive scheduler capability may be included with the multiprocessor 214. The preemptive scheduler 264 in various embodiments can be used to prioritize external data transfers as well.

In the embodiment of FIG. 2, the memory device 230 (or the memory package 1 (202)) may perform inter-channel data transfers as noted above. Inter-channel communications refers to communications between devices on different packages. For example, a first processor on die-1 may transfer data to a second processor on die-N using the inter-channel communication path 210. For purposes of this disclosure, the communication path 210 is shown as a dashed line to illustrate the direction of data flow. The data associated with the inter-channel communication path 210 may be routed over bus 251, which connects the in-package bus 262 to the I/O interface 245a of storage controller 270. The data may be routed through scheduler 243 and thereafter through the crossbar or packet switch module 218 on storage controller 218. The storage management processor 220 may be coupled to the I/O interface 245 and the crossbar 218 to control data flow. The inter-channel data may thereafter be sent via I/O interface 245b to the I/O interface 262 on die-N using bus 252. The I/O interface circuit 250 on die-N may route the data to the destination processor on die-N.

As shown by storage data read 212 and storage data write 260 data paths, the memory cores 216 on any of die-N can be used for external memory reads and writes from a host. Data written to, or read from, the memory core 216 of a particular die may be sent via a bus such as bus 251 or 252.

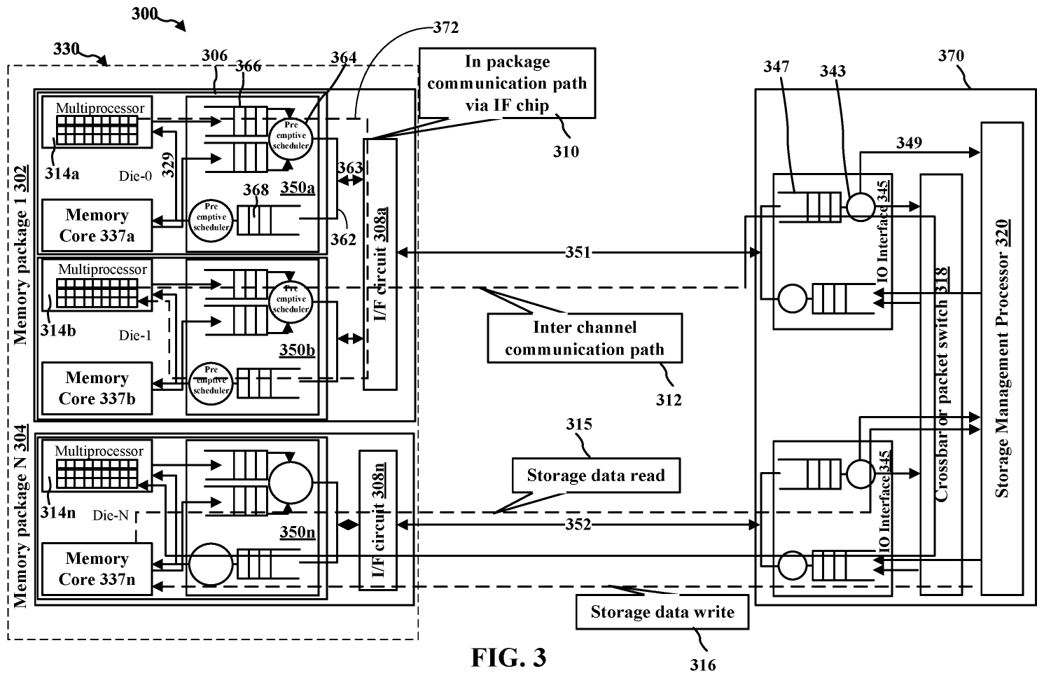

FIG. 3 is a block diagram of a distributed multiprocessor and memory device 300 that performs intra-package communication using an internal interface circuit 308. Depending on the implementation, the memory/processor device may include an individual memory package 1 (302). Alternatively, the device 330 may include each of the N packages arranged on a substrate, or a plurality of stacked substrates, or another suitable configuration. For example, the memory device of FIG. 3 may include a single device 330 housing the plurality of packages 1 through N (302, 304). In other embodiments, the memory device may include memory package 302 arranged on a distinct substrate and incorporating one or more dies within the package. Thus, while a surface 330 is shown to demonstrate that the memory packages 1-N (302, 304) can be implemented as a single, integrated memory device, the packages may have some other orientation without departing from the scope of the present disclosure. In addition, the individual dies may be stacked or formed as CBA dies or used with another configuration. The packages and dies may have any number of elements.

Interface circuits 308a-308n of FIG. 3 may be used in lieu of the in-package busses 262 of FIG. 2. Interface circuits 308a-n can be used to perform high capacity data routing between dies in a package and also can be used to mediate inter-channel communications, or external communications, e.g., over a network, with the storage controller. The interface circuits 308a-n can further be used to form serial or parallel connections between processors. In some embodiments, the interface circuits 308a-n can be used to perform other interface logic that would otherwise require a separate circuit element.

Like the device 230 of FIG. 2, the memory device 330 and the memory packages on the device 330 are capable of performing inter-die data transfers, for example, without the need or involvement of the storage controller 370. Similar to FIG. 2, device 330 may include an I/O interface 350a, 350b, 350n for each of the N dies in the N packages 302, 304. The number of dies can be different from the number of packages, and in various embodiments one package may include multiple dies. Each I/O interface may include a queue 366/368, which in turn can include the necessary registers or buffers for facilitating data transfers. Multiprocessor 314a may be coupled to the memory core in any of several different embodiments, with each element coupled to conductors such as conductor 329 to facilitate data transfer operations and memory retrieval procedures within a die.

In addition, in various embodiments, each of the dies may include preemptive schedulers 364. As described above, preemptive schedulers may include hardware that enable the processors in multiprocessor 314a, 314b, and 314n to initiate and conduct high priority data transfers. Intra package data transfers, e.g., from die-0 to die-1, can be prioritized and conducted without the need for involvement of the storage controller. Instead, the high priority data packets can be routed via data path 372 (e.g., via conductors/busses 362 and 363) through the I/O interface 350a, the interface circuit 308a, and the I/O interface 350b and to its destination processor on die-1, for example.

The data path 372 shows the flow of the conductors to interface circuit 308a for routing data from a first processor in multiprocessor 314a to a second processor in 314b on a separate die-1. In other embodiments, any of the processors in multiprocessor 314a can perform read and write operations to and from the memory in memory core 337a using one or more of internal data paths 329 and 362. The processor in multiprocessor 314 can also perform read and write operations to and from memory core 337b via interface circuit 308a. In addition, the different dies (e.g. die-0 and die-N) can transfer data to and from the processors or memory using inter-channel communication path 312, which routes the data through the storage controller 370 using I/O interface 345, scheduler 343 and registers 347 as described above. Under control of the storage management processor 320, for example, the data may be routed through crossbar/packet switch module 318 to its destination channel. In addition, host read operations 315 and write operations 316 can be performed by the storage controller using bus 352, for example. External data transfers can be performed as well.

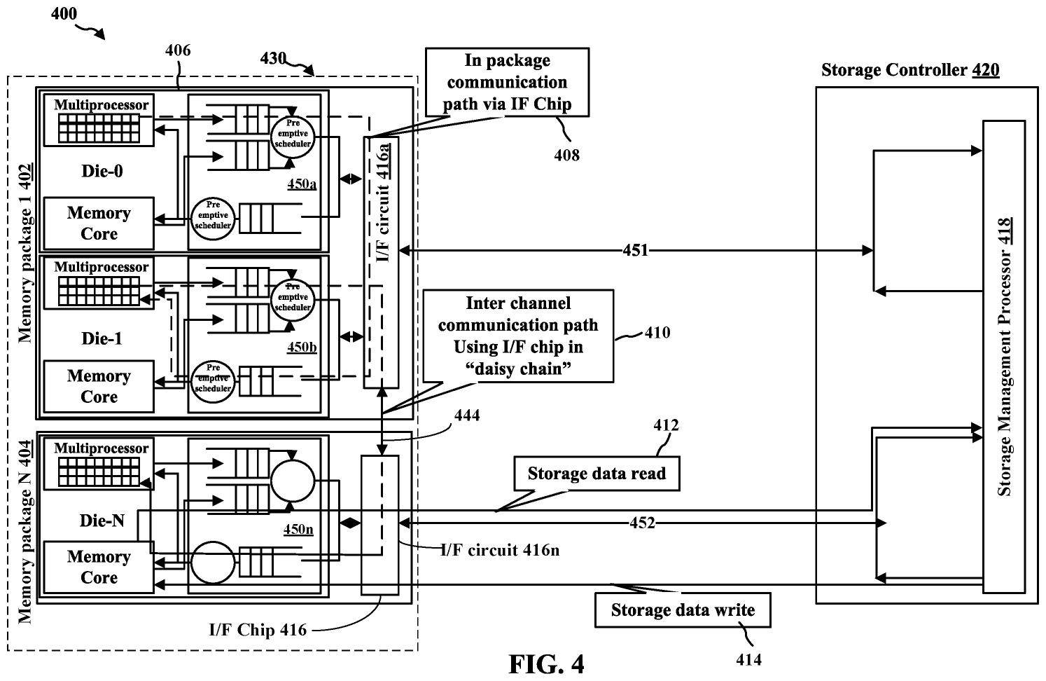

FIG. 4 is a block diagram 400 of a distributed multiprocessor and memory device 430 that can perform both intra-package and inter-channel communication using an internal interface circuit 416a. The memory device 430 is similar in certain respects to the devices of FIGS. 2 and 3. For example, the circuit 430 includes a plurality of memory packages 1-N, wherein two such example packages 402 and 404 are shown in the illustration. Examples of individual dies are also shown (die 0, 1 and N), noting that the number of dies may differ from the number of packages. As in previous embodiments, for example, a single package may include one to multiple dies. As shown, each such die includes its own processor circuitry (however physically distributed or localized on the dies), its own memory, and I/O interface circuits.

Further, as in previous embodiments, each die is coupled to each other die within a package using a plurality of conductors. Each die comprises preemptive schedulers to enable the processors to transfer data using different priority levels. Like in FIG. 3, the configuration of FIG. 4 includes a plurality of interface integrated circuit (IC) devices 416 for actively routing high capacity communications. For example, any processor on a die-0 in a package 402 can route data internally to and from any processor on another die-1 in the same package, using interface IC 416, without using the storage controller 420. In addition, like in previous embodiments, the storage controller 420 can perform external read and write operations assisted by its storage management processor 418. Examples include a data read 412, using the memory within device 430 and an available data bus 451, 452 between the storage controller 420 and the device 430. A data write 414 may similarly be performed.

In still another aspect of the present disclosure, each of the interface ICs 416a-n (two such ICs 416a and 416n are shown for exemplary purposes) are coupled together serially in a “daisy chain” manner using bus 444. The number of such busses 444 depends in one embodiment on the number of packages, with a total of N−1 busses being used to connect N packages. For instance, if sixteen packages are on the device, N−1=15 busses may be used to serially connect them. Such “inter-channel” or “inter-package” bus connections may be used to connect a plurality of memory/processor devices, each device having one or packages. Control logic in the I/O interfaces 450a-n or in the interface ICs 416a-n may be used to assist the processors in transferring data between any die on any other package. The storage controller 420 is not needed to perform internal inter-channel communications, meaning that any processor on any die of the device 430 can communicate via the interface ICs 416a, etc., with any processor or memory on any other die of any other package in the device. Inter-channel communications therefore can be conducted at high capacity, effectively eliminating latencies, path delays and other disadvantages due to the storage controller. Bandwidth can be increased for use in high performance applications. While the timing of each interface IC 416 through which data packets are routed must be taken into account, latencies can be minimized using a smart architecture by making path delays in interface ICs 416 as small as practicable.

Still referring to FIG. 4, the storage controller 420 can still perform external read and write operations on memory locations in the device 430, as well as external data transfers to or from a multiprocessor. For example, a data read operation 412 or a data write operation 414 can be conducted using bus 452. The processors in a location of device 430 can also communicate with the storage controller or transfer data to the storage controller over busses 451 and 452. It should also be noted that preemptive data transfers can be scheduled between different packages, enabling inter-channel communication of high priority communications internally within the device 430.

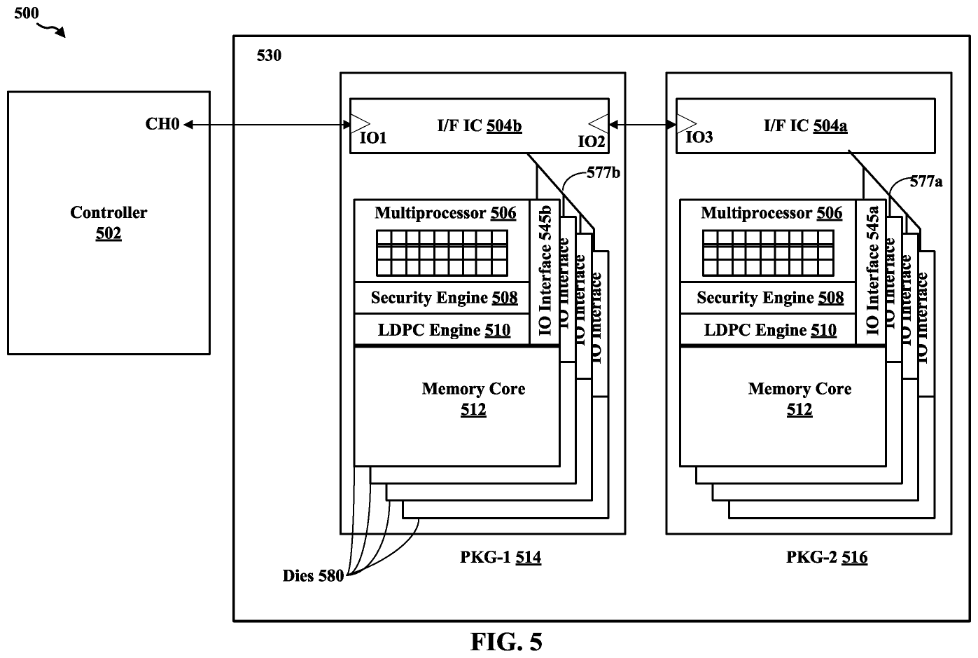

FIG. 5 is a block diagram of a distributed memory and processor architecture 500. FIG. 5 shows another example of the circuit in FIG. 4. While a device 530 using two packages 514 and 516 are demonstrated in this example, any number of packages may be used. Controller 502 may be a storage controller, or another type of controller that may be used to interface with device 530. To perform inter-channel communications and to communicate with controller 502, the interface ICs 504a and 504b include three operating I/O ports including IO1, IO2 and IO3, although multiple ports per package can also be used.

Each of packages 514 and 516 include four separate dies 580. The four dies are connected to each other and to the interface ICs 504a and 504b using a respective plurality of conductors 577a and 577b. Each individual die 580 may include multiprocessor 506 and memory core 512. As before, the processors of multiprocessor may be localized in a region of the die. In other embodiments, the multiprocessor may include processor distributed throughout the die. In some embodiments in which a CBA is used, the processors may be included on one of the stacked dies and the memory included on the other die. The memory core 512 may include non-volatile memory, such as NAND or NOR flash memory, or another technology. The memory core 512 may also include cache memory and volatile memory, or a combination of both. The memory core 512 and/or the processors may each use multiple cache levels. Like the processors, the memory in the memory core may be distributed in any suitable manner across the die 580.

Each die 580 may also include an I/O interface module 545a and 545b. The I/O interfaces may include one or more preemptive schedulers for performing multi-priority data transmissions. In other embodiments, the preemptive schedulers may be located in the interface ICs 504a, 504b, instead. In an embodiment, the interface ICs 504a and 504b are designed to enable high capacity communications at high speeds both with respect to inter-die and inter-channel (inter-package) communications.

The controller 502 may communicate with the device 530 using one or more I/O paths or busses labeled CHO. The controller may execute external write and read operations to and from the packages 514 and 516, or any die 580 located therein.

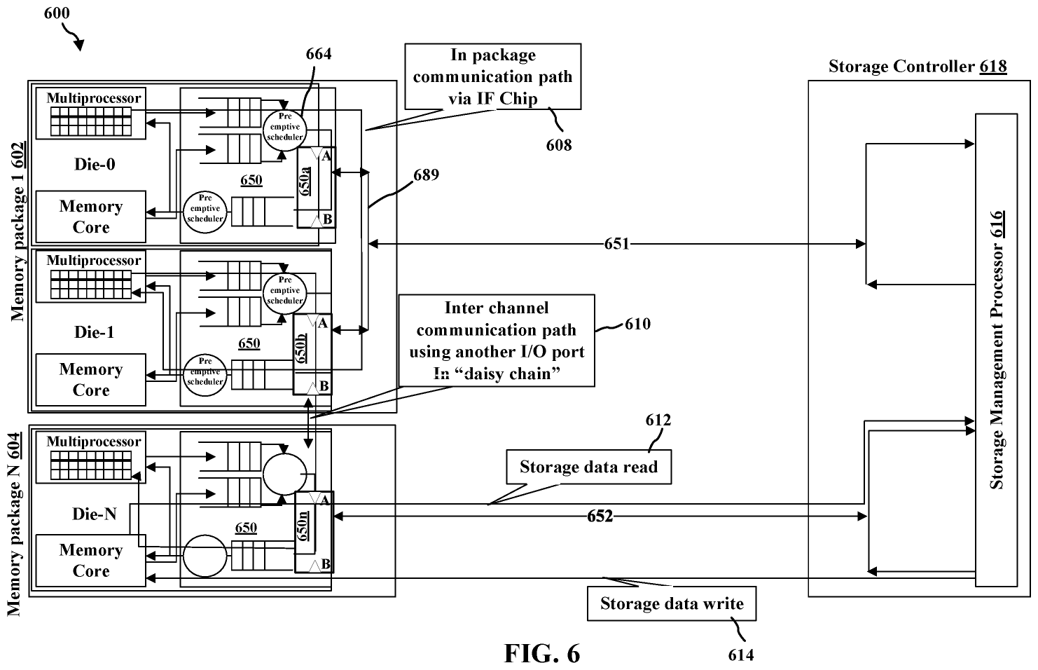

FIG. 6 is a block diagram of a distributed multiprocessor and memory device 600 that performs intra-package and inter channel communication using an internal I/O interface instead of a dedicated integrated circuit. In this example, memory packages 1-N may be implemented as part of a single device, e.g., using a printed circuit board on which the packages can be arranged, or using other suitable techniques. FIG. 6 is similar to the circuits shown in FIG. 4 and FIG. 5, and includes one or more dies 0, 1, . . . N included in packages 602 and 604, where the number of packages may vary. As in previous examples, each die may include processors memory, and I/O interface 650, and a plurality of preemptive scheduling circuits 664 for conducting multi-priority communications.

In this embodiment, both inter-channel and in-package communications can be performed without storage controller intervention. However, in lieu of using interface ICs as in FIG. 4, the memory device 600 includes a portion of the I/O interface labeled 650a, 650b, . . . 650n. Each of the interface portions, along with conductors or busses 610, 689 between the die and packages, enable the processors to conduct both in package and inter-channel communications. More specifically, in the embodiment of FIG. 6, the portions I/O interfaces 650a, 650b, . . . 650n allows one processor from one die to exchange data with any of the other processors on the same die, a different die, or a different package. In the embodiment shown, each of the I/O sections 650a, 650b, . . . 650n may include two bi-directional ports to enable data to travel across the busses to and from each adjacent package, or to or from a die within the package. In some embodiments, the memory packages at the end of the adjacent set may need only one such port because there is only one downstream adjacent package. In other embodiments, multiple ports may be used. The I/O sections 650, 650b, . . . 650n may include conductors that are connected in a daisy chain or serial manner to enable data packets to originate from any die in any of the packages. One of the benefits of this configuration is that, because no interface IC is used in this embodiment, the latencies of passing data through active circuits may be reduced, as well as the amount of intervening control logic. Thus communications can be transferred back and forth at high speeds with lower latencies, all internally within the plurality of packages 600.

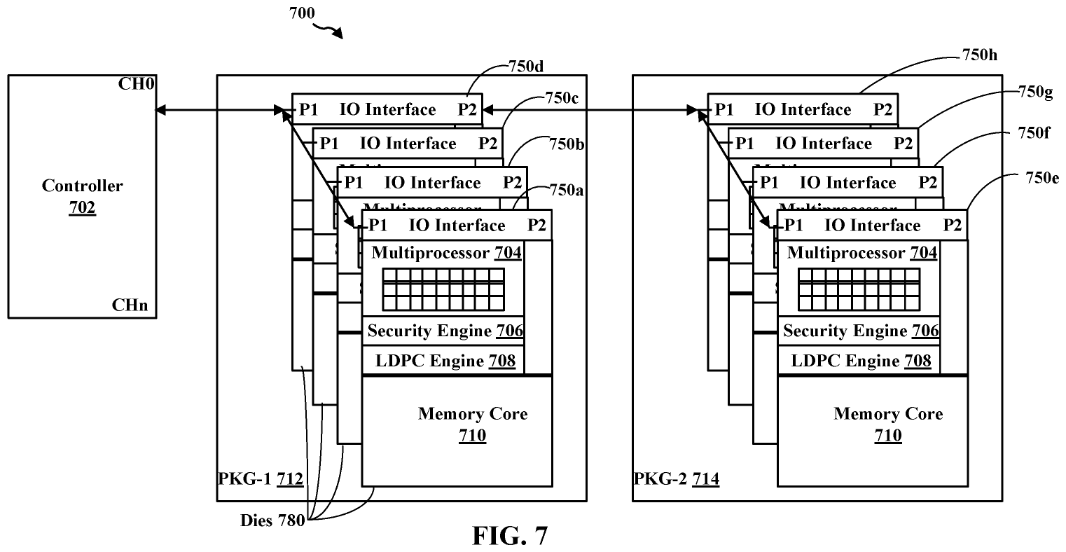

FIG. 7 is a block diagram 700 of an exemplary configuration of a portion of the circuit of FIG. 6. In this example, each of two packages 712 and 714 are occupied by four separate dies 780. In this embodiment, each die 780 has a separate I/O interface. Package 712 includes I/O interfaces 750a, 750b, 750c and 750d. Package 714 includes 750e, 750f, 750g and 750h. One of the benefits of this set of embodiments is that IBC functionality can be merged into the CMOS on the memory die. Data can also be transferred without passing through the storage controller 702 for both intra-package and inter-channel communications, and point to point transfers can occur without IBC. As shown in FIG. 7, at least two ports or sets of I/O modules may be available on each die to support consecutive data transfers. While four dies 780 are shown per package 712 and 714 each, additional packages may be bonded or arranged adjacent the device and can be included as part of the architecture.

The memory device 700 provides a new inter-processor communication architecture to support fully meshed real-time low latency interconnections across multiprocessor units or distributed processors adjacent to or bonded to memory core dies, which can be ideal as high-sophistication computational storage architecture.

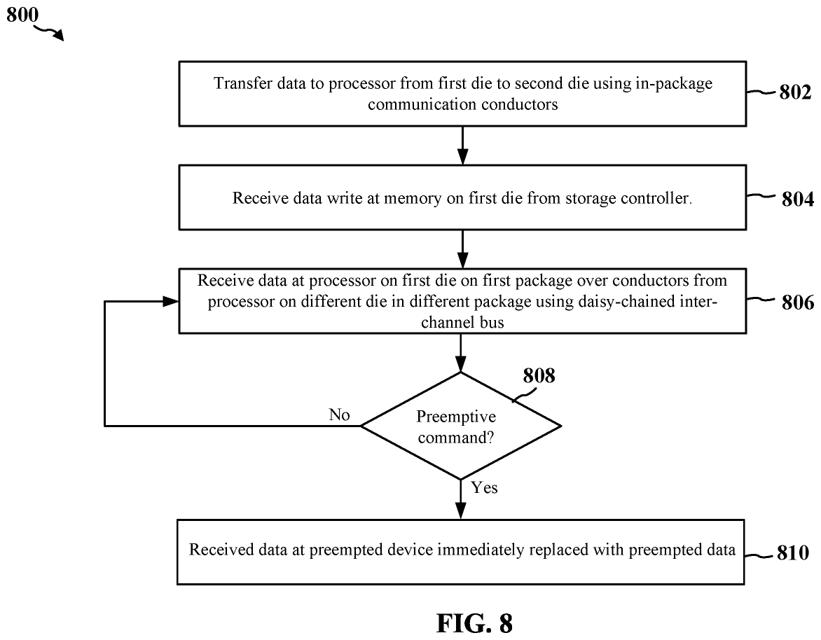

FIG. 8 is a flowchart describing intra-package and inter-channel communication. At exemplary step 802, a processor may conduct a data transfer from its location on a first die to another processor or memory location on a second die using in-package communication conductors or other I/O circuits. In addition to these device-internal communications, the memory device at exemplary step 804 can also receive external data write requests at a memory on a first die from the external storage controller. In addition, the external storage controller can also perform memory read operations using the memory device.

At exemplary step 806, a processor on a first die in the memory package may receive data over conductors or busses (or other I/O circuits), both within and external to the first die, from a processor on a different die in a different package using a daisy-chained inter-channel bus. If no preempting or higher priority communications are received, the processor can proceed to receive the present data transfer without delay. If, however, the processor receives a preempt command, it may immediately suspend the data transfer to make room on the bus for an exemplary urgent, high priority data transfer to take place immediately. Alternatively, if another processor is currently using the bus to conduct a regular or low priority data transfer, the first processor may use the preemption scheduler to suspend the ongoing data transfer so that the first processor can transmit a high priority communication to a destination processor or memory location. Thus, as in exemplary step 810, the received data at the preempted device can immediately be replaced with preempted data. In some embodiments, two priority levels may be sufficient. In other embodiments, however, the memory device can use preemption schedulers with multiple priority levels in order to help ensure that the bus is being used for the most necessary purposes first, and thereafter transfers for all the lower-priority data can resume.

Circuits such as the preemptive schedulers and I/O components may be implemented using any suitable hardware architecture, including conventional logic, DSPs, FPGAs, etc. Alternatively, or in addition, the preemptive schedulers and other functions on the dies may be implemented using a dedicated or general purpose processor running code.

The various aspects of this disclosure are provided to enable one of ordinary skill in the art to practice the present invention. Various modifications to exemplary embodiments presented throughout this disclosure will be readily apparent to those skilled in the art, and the concepts disclosed herein may be extended to other magnetic storage devices. Thus, the claims are not intended to be limited to the various aspects of this disclosure, but are to be accorded the full scope consistent with the language of the claims. All structural and functional equivalents to the various components of the exemplary embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) in the United States, or an analogous statute or rule of law in another jurisdiction, unless the element is expressly recited using the phrase “means for” or, in the case of a method claim, the element is recited using the phrase “step for.”

1. A memory device, comprising:
a controller; and
a plurality of packages coupled to the controller, each of the plurality of packages comprising a plurality of dies having processors and memory cells, the plurality of dies in a package being coupled together within the package and with other packages of the plurality of packages via conductors,
wherein one or more processors on a first die in a first package of the plurality of packages is configured to transfer data internally within the memory device by transferring the data directly to one or more processors on a second die in a second package of the plurality of packages via the conductors independent of the controller.

2. The memory device of claim 1, wherein the one or more processors on the first die is further configured to write or read data to or from one or more of the memory cells on the second die, the written data being accessible to another processor for use in one or more computing functions.

3. The memory device of claim 1, wherein each of the processors comprises a priority scheduler configured to enable the processor to preemptively perform high priority data transfers between any other of the processors or memory cells.

4. The memory device of claim 1, wherein each of the processors on the plurality of dies is further configured to perform distributed computing functions.

5. The memory device of claim 4, wherein each of the processors on the plurality of dies is further configured to perform at least one of dedicated graphics functions, artificial intelligence functions, machine learning functions, distributed computing functions, or search functions.

6. The memory device of claim 1, wherein at least a portion of the conductors between the plurality of dies coupled together within the package comprises an in-package interface bus.

7. The memory device of claim 6, wherein in-package interface buses corresponding to adjacent or stacked packages on a substrate are connected serially and are each configured with an input port and an output port to enable inter-channel communications.

8. The memory device of claim 1, further comprising, for each of the packages, an interface integrated circuit (IIC) electrically connected to each of the dies within the package, the IICs configured to enable in-package communications.

9. The memory device of claim 8, wherein the IICs corresponding to adjacent or stacked packages on a substrate are coupled together serially and are configured to enable the dies to perform inter-channel communications.

10. The memory device of claim 1, wherein each of the packages includes at least one die comprising dedicated control circuitry for use with dies comprising memory cells.

11. The memory device of claim 1, wherein the plurality of dies within one or more packages comprises a CMOS Bonded Array (CBA).

12. A device for intra-package and inter-channel processor communication, comprising:
a controller, and
a plurality of packages on a substrate and coupled to the controller, each package of the plurality of packages comprising a plurality of dies, each die of the plurality of dies having processors and memory cells, the plurality of dies coupled together within the package and with other packages of the plurality of packages via conductors,
wherein one or more processors on a first die in a first package of the plurality of packages is configured to transfer data internally within the device by transferring the data directly between the processor and another processor or memory cells on a second die in a second package of the plurality of packages via the conductors independent of the controller.

13. The device of claim 12, wherein each of the processors comprises a priority scheduler to enable the processor to preemptively perform high priority data transfers to another processor or to the memory cells.

14. The device of claim 12, wherein each of the processors is configured to perform distributed computing functions within and across the plurality of packages using other processors or memory cells.

15. The device of claim 12, wherein at least a portion of the conductors between the dies within each of the packages comprises an in-package interface bus configured to enable processors to send and receive in-package communications.

16. The device of claim 12, wherein the first and second dies are located within a same package.

17. The device of claim 12, further comprising, for each of the plurality of packages, an interface integrated circuit (IC) coupled to each of the plurality of dies within the package, the interface ICs configured to enable in-package data transfers by the processors.

18. The device of claim 17, wherein the interface ICs are further connected serially between adjacent packages and configured to enable the processors to perform inter-channel communications using the memory cells.

19. An apparatus, comprising:
a package arranged on a substrate and comprising a plurality of dies with each die having processors and an input/output (I/O) interface coupled to other dies of the plurality of dies via conductors and configured to connect to an external storage controller,
wherein the I/O interface is configured to enable a processor on one die of the plurality of dies to perform an in-package data transfer to or from another processor on another die of the plurality of dies and to perform inter-channel data transfers with processors outside the apparatus via the conductors independent of the external storage controller.

20. The apparatus of claim 19, further comprising an interface integrated circuit (IIC) coupled to the I/O interfaces and configured to connect to the external storage controller, the IIC configured to enable in-package communications between different dies within the package and inter-channel communications via the external storage controller between processors on different packages.
